(19) United States
(12) Patent Application Publication
(10) Pub. No.: US 2026/0246268 A1
(43) Pub. Date: Aug. 20, 2026

(54) HIGH VOLTAGE HOT-SWAP CONTROL

(71) Applicant: Monolithic Power Systems, Inc., Kirkland, WA (US)

(72) Inventors: Jason Bone, Round Rock, TX (US); Vipindas Pala, San Jose, CA (US)

(21) Appl. No.: 19/334,773

(22) Filed: Sep. 19, 2025

Related U.S. Application Data
(60) Provisional application No. 63/760,323, filed on Feb. 19, 2025.

(51) Int. Cl. H02J 1/00; H03K 17/16

(52) U.S. Cl. CPC H02J 1/001; H03K 17/163

(57) ABSTRACT

A hot-swap circuit includes a normally-on JFET and a switch connected in series between an input node and an output node, which are controlled by a drive circuit and a controller, respectively. A gate of the normally-on JFET is connected to the output node by the drive circuit. The controller regulates the switch based on an output voltage and a current flowing through the switch, allowing the output node to be connected to the input node when both the JFET and switch are turned on.

This application claims the benefit of U.S. Provisional Patent Application No. 63/760,323, filed Feb. 19, 2025, under 35 U.S.C. § 119(e).

### FIELD OF THE INVENTION

The present invention generally relates to integrated circuits, and more particularly but not exclusively relates to switches and protection for electronic devices.

### BACKGROUND

Hot-swap circuits have switches that are employed in electronic devices to connect and disconnect an input power supply to a load, without shutting down the power supply. These switches are typically employed in removable circuit cards (e.g., add-on boards), hot-swap storage devices, electronic fuse, and other applications involving connection of an input power supply to a load. A typical switch in such applications has a terminal connected to the input power supply and an opposing terminal connected to the load. As a particular example, the switch can be used to allow a server (the load in this example) to operate while replacing or upgrading peripherals, e.g., hard drives, power supplies, and network cards. The switch can be implemented using a power transistor, MOSFET, JFET, and SiC.

### SUMMARY

In one embodiment, a hot-swap circuit has an input node, an output node, an input return node and an output return node. The hot-swap circuit receives an input voltage between the input node and the input return node, provides the output voltage between the output node and the output return node, with the input return node and the output return node coupled to a power ground. The hot-swap circuit further has a normally-on JFET, a switch, a drive circuit and a hot-swap controller. The normally-on JFET and the switch are connected in series between the input node and the output node. The hot-swap circuit connects the output node to the input node when both the normally-on JFET and the switch are turned on. The drive circuit connects a gate of the normally-on JFET to the output node. The hot-swap controller controls the switch based on the output voltage and a current flowing through the switch.

In another embodiment, a method of operating a hot-swap circuit is disclosed. Receiving an input voltage between an input node and an input return node. Providing an output voltage between an output node and an output return node. Controlling a switch which is connected in series with a normally-on JFET between the input node and the output node based on the output voltage and a current flowing through the switch. Connecting the output node to the input node when both the normally-on JFET and the switch are turned on. A gate of the normally-on JFET is connected to the output node.

These and other features of the present disclosure will be readily apparent to persons of ordinary skill in the art upon reading the entirety of this disclosure, which includes the accompanying drawings and claims.

### BRIEF DESCRIPTION OF DRAWINGS

The present invention can be further understood with reference to the following detailed description and the appended drawings, wherein like elements are provided with like reference numerals. These drawings are only for illustration purpose, thus may only show part of the devices and are not necessarily drawn to scale.

FIG. 1A shows a schematic diagram of a hot-swap circuit 100 for connecting an input power supply to a load in accordance with an embodiment of the present invention.

FIG. 1B illustrates a functional block diagram of a hot-swap controller 103 in accordance with an embodiment of the present invention.

FIG. 2 shows waveforms illustrating startup sequences of the hot-swap circuit 100 in accordance with an embodiment of the present invention.

FIG. 3A shows a schematic diagram of a hot-swap circuit 200 for connecting the input power supply to the load in accordance with an embodiment of the present invention.

FIG. 3B shows a block diagram of the integrated circuit 201 in accordance with an embodiment of the present invention.

FIG. 4 shows a schematic diagram of a hot-swap circuit 200A for connecting the input power supply to the load in accordance with an embodiment of the present invention.

FIG. 5 shows a schematic diagram of a hot-swap circuit 200B for connecting the input power supply to the load in accordance with an embodiment of the present invention.

FIG. 6 shows a schematic diagram of a hot-swap circuit 300 for connecting the input power supply to the load in accordance with an embodiment of the present invention.

FIG. 7 shows a schematic diagram of a hot-swap circuit 400 for connecting the input power supply to the load in accordance with an embodiment of the present invention.

FIG. 8 shows a schematic diagram of a hot-swap circuit 500 for connecting the input power supply to the load in accordance with an embodiment of the present invention.

FIG. 9 shows a schematic diagram of a hot-swap circuit 600 for connecting the input power supply to the load in accordance with an embodiment of the present invention.

FIG. 10 shows a schematic diagram of a hot-swap circuit 700 for connecting the input power supply to the load in accordance with an embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications, and equivalents, which may be included within the spirit and scope of the invention as defined by the appended claims. Furthermore, in the following detailed description of the present invention, numerous specific details are set forth to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

Hot-swap circuits protect circuitry on its output, e.g., a load, from transients on its input. In particular, the input is protected from undesired shorts and transients coming from its output. Some applications, e.g., telecom, server, and AI data centers, are moving to high voltage levels e.g., 180V, −180V, 200V, −200V, 400V, −400V, 800V or −800V, for bus distribution, which requires a high voltage hot-swap circuit to support. The ability to migrate technology to support high voltage distributions is very challenging due to limited technology, devices, and cost. Embodiments of the present disclosure provide a hot-swap circuit suitable for such high voltage applications.

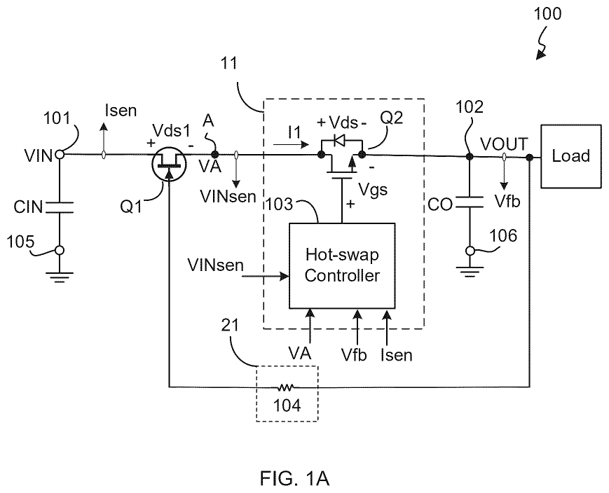

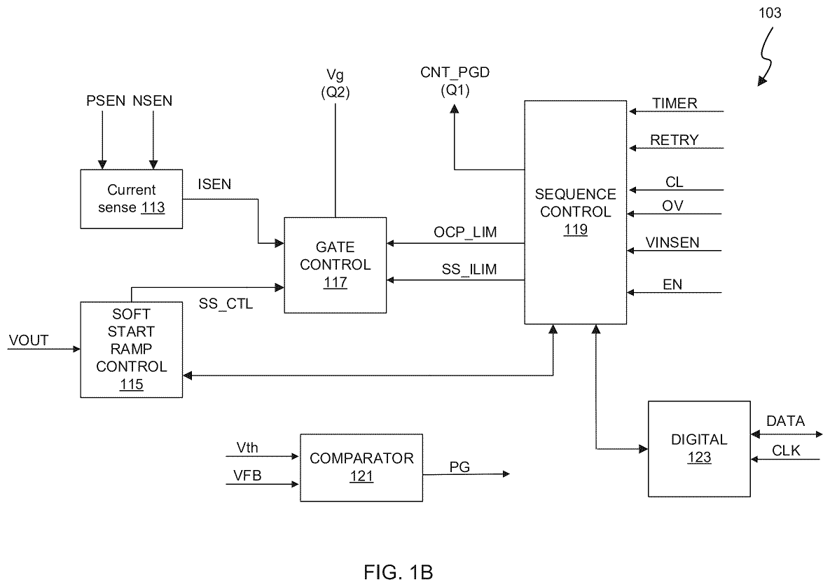

FIG. 1A shows a schematic diagram of a hot-swap circuit 100 for connecting an input power supply to a load in accordance with an embodiment of the present invention. The input power supply provides an input voltage VIN, which is higher than 180V or lower than −180V. The hot-swap circuit 100 includes an input node 101, an output node 102, an input return node 105, an output return node 106, a switch Q1, a switch Q2, a hot-swap controller 103, and a drive circuit 21 coupled between the output node 102 and a gate of the switch Q1. The switches Q1 and Q2 are connected in series between the input node 101 and the output node 102, and the hot-swap circuit connects the output node 102 to the input node 101 when both the switches Q1-Q2 are turned on. The hot-swap circuit receives the input voltage VIN between the input node 101 and the input return node 105 and provides an output voltage VOUT to a load between the output node 102 and the output return node 106. The switch Q2 and the hot-swap controller 103 may be integrated into an integrated circuit (IC) 11 or may be discrete devices.

In one embodiment, the switch Q1 is a normally-on Junction Field-Effect Transistor (JFET), and the switch Q2 is a Metal-Oxide-Semiconductor Field Effect Transistor (MOSFET). Herein after using JFET Q1 instead of switch Q1. As shown in FIG. 1A, a first terminal (i.e., Drain) of the JFET Q1 is connected to the input node 101, a second terminal (i.e., Source) of the JFET Q1 is connected to a first terminal (i.e., Drain) of the switch Q2 at a node A, and a second terminal (Source) of the switch Q2 is connected to the output node 102. The drive circuit 21, which can be a resistor 104, connects the gate of the JFET Q1 to the output node 102. This connection regulates a voltage VA at the node A, ensuring that a drain-source voltage Vds of the switch Q2 is clamped to a safe level, i.e., no higher than a pinch-off voltage Vpinch_off of the JFET Q1. When the hot-swap controller 103 drives the gate of the switch Q2, the JFET Q1 regulates the voltage VA, allowing current I1 to flow through the switch Q2. The input voltage VIN can range from 100V to 1000V.

The drain-source voltage Vds1 of the JFET Q1 is much higher than the drain-source voltage Vds of the switch Q2 during startup of the output voltage VOUT. The JFET Q1 provides a regulation of the drain-source voltage Vds of the switch Q2 to the safe level. This enables the switch Q2 to be designed as a low-voltage device, which can simplify the design and reduce costs.

The hot-swap controller 103 controls the switch Q2, e.g., based on a feedback signal Vfb representative of the output voltage VOUT and a feedback signal Isen representative of the current I1 flowing through the switches Q1 and Q2. In one embodiment, the hot-swap controller 103 implements a soft start function to gradually increase the output voltage VOUT from a first voltage (e.g., 0V) to a second voltage HV (e.g., approximately equal to the input voltage VIN). This controlled startup ensures a smooth inrush current and prevents potential damage to the system. Additionally, the hot-swap controller 103 can be configured to provide various protection features. For example, the hot-swap controller 103 can limit the current I1 flowing through the switches Q1 and Q2 to prevent overcurrent conditions. The hot-swap controller 103 can also monitor and control the power consumed by the switch Q2 to prevent overheating or excessive energy loss. Furthermore, the hot-swap controller 103 can regulate the temperature of the switch Q2 to ensure reliable operation within a safe thermal range.

FIG. 1B illustrates a functional block diagram of a hot-swap controller 103 in accordance with an embodiment of the present invention. A current sense block 113 is coupled between terminals PSEN and NSEN to produce a sense signal, e.g., ISEN, corresponding to the current I1 flowing through the switch Q2. A soft start ramp control block 115 is coupled to receive the output voltage VOUT and in response produce a soft start ramp control signal (“SS_CTL”). A comparator 121 is coupled to receive the feedback VFB and compare the feedback VFB to a voltage threshold Vth to produce a power good signal PG indicating sequencing process can continue. A sequence control block 119 is coupled to receive external control signals: timer (“TIMER”), retry (“RETRY”), clamping voltage (“CL”), Over Voltage (“OV”), input voltage sensing signal (“VINSEN”), and enable (“EN”). The sequence control block 119 is in bidirectionally coupled to the soft start ramp control block 115 and the digital block 123. The digital block 123 is coupled to receive a clock signal and transfer data. In response to the control signals, the sequence control block 119 produces an over-current protection limit (“OCP_LIM”) signal and a soft start limit (“SS_ILIM”) signal, e.g., to limit the maximum inrush current. A gate control block 117 is coupled to the current sense block 113, soft start ramp control block 115, and the sequence control block 119.

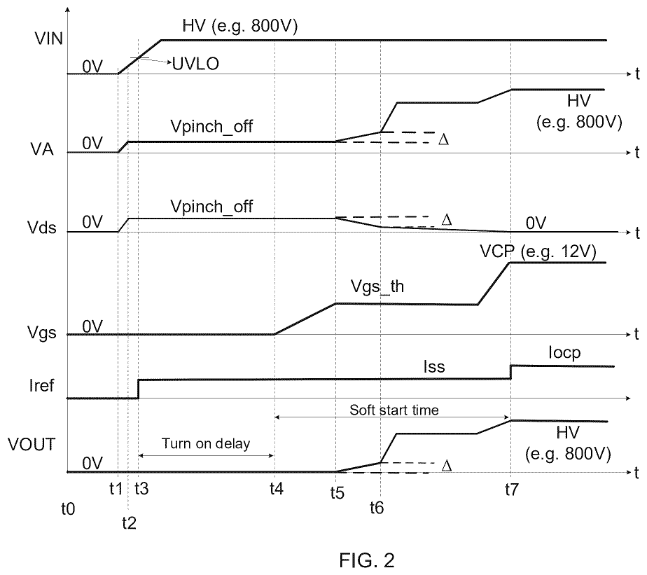

FIG. 2 shows waveforms illustrating startup sequences of the hot-swap circuit 100 in accordance with an embodiment of the present invention. As shown in FIG. 2, the hot-swap circuit 100 has a specific startup sequence that ensures reliable and controlled operation. To initiate the hot-swap procedure, the input voltage VIN must be within a specified range. This range is defined by the minimum and maximum input voltage requirements of the hot-swap circuit 100, which are determined by the hot-swap controller's operating voltage range and the application's input voltage specifications. The hot-swap controller 103 is designed to operate within a specific voltage range, and its operating voltage range must be compatible with the application's input voltage requirements to ensure proper function and reliability.

At time t1, the input voltage VIN at the input node 101 begins to increase in response to an event, e.g., inserting a circuit card that incorporates the JFET Q1 and the switch Q2 into a live backplane. During this period, the switch Q2 is maintained off, and the JFET Q1 is on. As a result, the voltage VA and the drain-source voltage Vds of the switch Q2 increase.

At time t2, the hot-swap circuit 100 clamps the voltage VA, ensuring that the drain-source voltage Vds of the switch Q2 remains at or below the pinch-off voltage Vpinch_off of the JFET Q1. The JFET Q1 operates at or below its pinch-off voltage. In this region, the JFET acts as variable resistor. The voltage drop across the JFET Q1 is VIN-Vpinch_off. The drain-source voltage Vds of the switch Q2 equals the pinch-off voltage Vpinch_off. Meanwhile, the switch Q2 remains off, with its gate-source voltage Vgs being zero, resulting in no current flow through the switch Q2.

At time t3, the voltage VINSEN indicating the input voltage VIN exceeds undervoltage lock out (UVLO) threshold of the hot-swap controller 103, which is a predetermined minimum voltage level below which the hot-swap controller 103 is prevented from operating to ensure reliable function and prevent damage. After a predetermined turn-on delay time period, at time t4, the hot-swap controller 103 initiates a soft start turn-on of the switch Q2 by increasing its gate-source voltage Vgs to a threshold voltage Vgs_th, below which point the switch Q2 remains nonconductive. During this time, the JFET Q1 continues to operate as a variable resistor.

Between times t4-t6, the hot-swap controller 103 creates a reference ramp voltage (not shown) for soft start that is compared to the output voltage VOUT through a feedback loop. As the gate of the switch Q2 turns on, the output voltage VOUT is actively compared to the reference ramp voltage. If the output voltage VOUT exceeds the reference ramp voltage, the gate control circuit pulls down on a current source (e.g., 26 uA) to slow down the charging of the gate of the switch Q2, thereby decreasing a slew rate of the output voltage VOUT. This feedback control mechanism continues throughout the entire soft start procedure.

Between times t5-t6, the switch Q2 is conductive, and the voltage VA increases to ΔV+Vpinch_off. The drain-source voltage Vds of the switch Q2 decreases to Vpinch_off-ΔV. The output voltage VOUT increases to ΔV.

Between times t6-t7, the hot-swap controller 103 uses the soft start procedure to produce the desired output voltage VOUT via analog or digital means. If the current I1 exceeds a soft start current limit Iss, which is below the allowed maximum rush current, the hot-swap controller 103 will regulate the gate of switch Q2 until the current I1 falls below the soft start current limit Iss. The hot-swap controller 103 stays in regulation of the current I1 during soft start.

At time t7, the soft start procedure is finished successfully, the output voltage VOUT reaches the high voltage HV (e.g., approximately 800V), the current limit of the current I1 transitions from the soft start current limit Iss to an over current protection (OCP) limit Iocp.

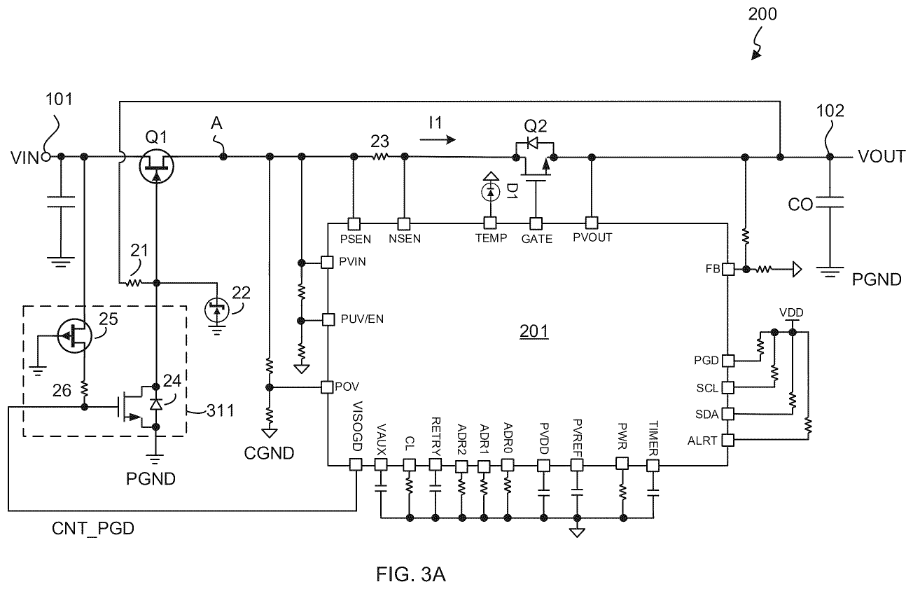

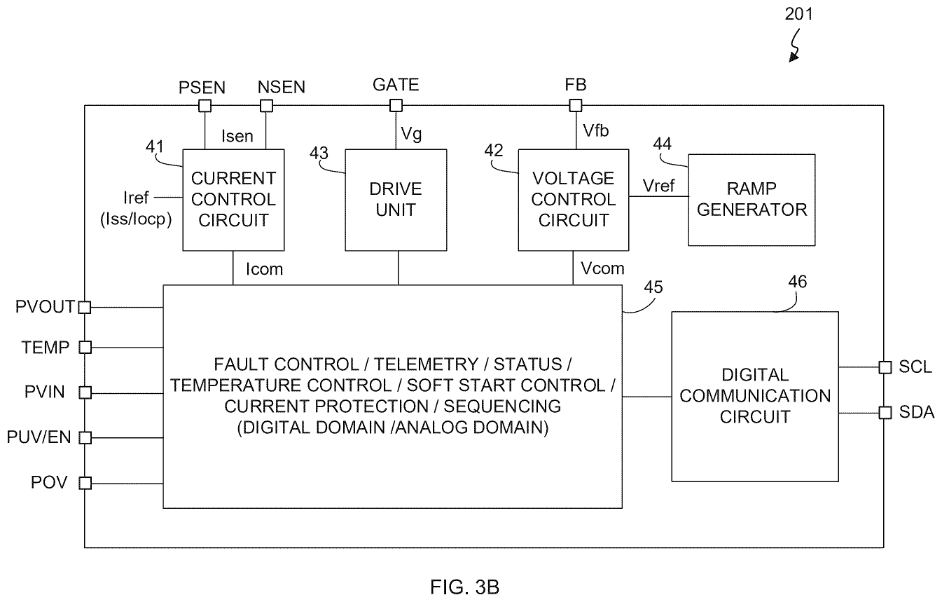

FIG. 3A shows a schematic diagram of a hot-swap circuit 200 for connecting the input power supply to the load in accordance with an embodiment of the present invention. The hot-swap circuit 200 includes the JFET Q1, the switch Q2, the drive circuit 21, and an integrated circuit 201. In the example of FIG. 3A, the hot-swap controller 103 of FIG. 1A is implemented by the integrated circuit 201. A gate protect circuit 22 is coupled to the gate of the JFET Q1, to protect the JFET Q1. In one embodiment, the gate protect circuit 22 comprises a Zener diode. In one embodiment, a turn-on circuit 311 including a switch 25 and a switch 24 is employed to control a turn-on sequence of the JFET Q1, with gate near zero voltage when there is no bias. In this embodiment, the switch 25 is a JFET, and the switch 24 is a MOSFET, and a resistor 26 is coupled between a source of the switch 25 and the gate of the switch 24. The gate of the switch 24 is coupled to a reference signal CNT_PGD provided by the integrated circuit 201. The turn-on circuit 311 can be implemented in various ways and is not restricted to the specific configuration shown in FIG. 3A. Other active components, such as Zener diodes, transistors, or additional switches, may also be included.

As shown in FIG. 3A, the integrated circuit 201 has a plurality of pins. A pin VISOGD provides the reference signal CNT_PGD. A pin PVOUT is connected to the output node 102 and the source of the switch Q2. A pin GATE is connected to the gate of the switch Q2. Pins NSEN and PSEN are used to sense the current I1 that flows through the switch Q2. The pin NSEN is connected to a terminal of an input sense resistor 23 and the pin PSEN is connected to another terminal of the input sense resistor 23. A pin PVIN is connected to the source of the JFET Q1 to read back the input voltage VIN. A pin PUV/EN is a control input that turns the integrated circuit 201 on and off. The pin PUV/EN can be connected to a resistor divider between the pin PVIN and a reference ground CGND for UVLO. A pin POV is an over-voltage enable input. Pulling the POV pin high will turn off the switch Q2. The pin POV can be connected to a resistor divider between the pin PVIN and the reference ground CGND to set the over-voltage protection threshold. Pins SDA, SCL, ALERT connect to a communication bus (e.g., PMBus). A pin PGD provides a power good signal indicating successful output voltage ramp of the switch Q2, this allows for indication to system of ability to operate at full power. A pin FB is configured to receive the feedback signal Vfb representative of the output voltage VOUT, e.g., connected to a resistor divider. A pin TEMP is used to measure an external temperature (e.g., a junction temperature of the switch Q2) via a diode D1 in this embodiment. The temperature measurement can also be achieved using various types of sensors, including NTC (Negative Temperature Coefficient) thermistors, PTC (Positive Temperature Coefficient) thermistors, thermocouples, digital temperature sensors, or isolated temperature devices.

In one embodiment, the integrated circuit 201 has a separate reference ground CGND, which is distinct from a system ground PGND, to which the input voltage VIN and output voltage VOUT are referenced. This separation of grounds helps to prevent high-voltage stress on the integrated circuit 201.

FIG. 3B shows a block diagram of the integrated circuit 201 in accordance with an embodiment of the present invention. In the example of FIG. 3B, the integrated circuit 201 comprises a current control circuit 41, a voltage control circuit 42, and a drive unit 43.

The current control circuit 41 is configured to receive a current reference signal Iref and a current sense signal Isen indicative of the current I1 flowing through the switch Q2. Based on the current sense signal Isen and the current reference signal Iref, the current control circuit 41 generates a current control signal Icom to ensure the current I1 does not exceed a preset current limit, i.e., the soft start current limit Iss during the soft start procedure and the OCP limit Iocp after the soft start procedure.

The voltage control circuit 42, which receives the feedback signal Vfb and a voltage reference signal Vref. Based on the feedback signal Vfb and the voltage reference signal Vref, the voltage control circuit 42 generates a voltage control signal Vcom to ensure the feedback signal Vfb following the voltage reference signal Vref. In one embodiment, the voltage reference signal Vref is provided by a ramp generator 44 which may be implemented in a digital or an analog domain. The ramp generator 44 provides the voltage reference signal Vref with a programmable slew rate during the soft start procedure, so that the output voltage VOUT has a controlled slew rate during the soft start procedure. This controlled slew rate will ensure there is no excessive inrush current that could possibly cause damage.

The drive unit 43 provides the switch control signal Vg to the gate of the switch Q2 based on the current control signal Icom, the voltage control signal Vcom, and other signals provided by a control unit 45. One partial of the control unit 45 may be implemented in a digital domain, and another partial of the control unit 45 may be implemented in an analog domain. The control unit 45 can implement many functions, such as fault control, telemetry control, status control, temperature control, soft start control, current protection, sequencing control, and so on.

The control unit 45 can provide information to a system controller via a digital communication circuit 46, enabling the system controller to have detailed information about the operation of the hot-swap circuit 200. The system controller can also set parameters (e.g., the soft start current limit Iss, the OCP limit Iocp, and so on) of the integrated circuit 201 via the digital communication circuit 46.

As described above, to control the output voltage VOUT increasing from 0V to a maximum value, e.g., approximately equal to the input voltage VIN, while limiting the current I1 flowing through the switch Q2, a combination of analog and digital techniques can be employed. The voltage reference Vref is used to adjust the output voltage VOUT via the voltage control circuit 42, ensuring that it remains within a specified tolerance, during and after the soft start procedure. Additionally, a current sensing circuit monitors the current I1, and the current control circuit 41 detects if the current sense signal Isen exceeds a predetermined current limit. If an overcurrent condition is detected, the output voltage VOUT is reduced or the switch Q2 is turned off to prevent damage. The integrated circuit 201 implements a power limit function and the ability to set the current limit during the soft start procedure. The ability to set the soft start current limit Iss during the soft start procedure allows it to be programmed lower than the OCP limit Iocp. When the output voltage rises high enough to trigger power good indication, the current limit is transitioned from the soft start current limit Iss to the OCP limit Iocp.

The hot-swap circuit 200 may incorporate a reference circuit to establish a virtual ground for the integrated circuit 201, thereby reducing voltage stress on the integrated circuit 201 from the input voltage VIN, which helps to prevent damage and ensure reliable operation of the hot-swap circuit 200A. The reference circuit can be designed to provide a precise voltage reference, allowing the integrated circuit 201 to operate within its specified tolerance.

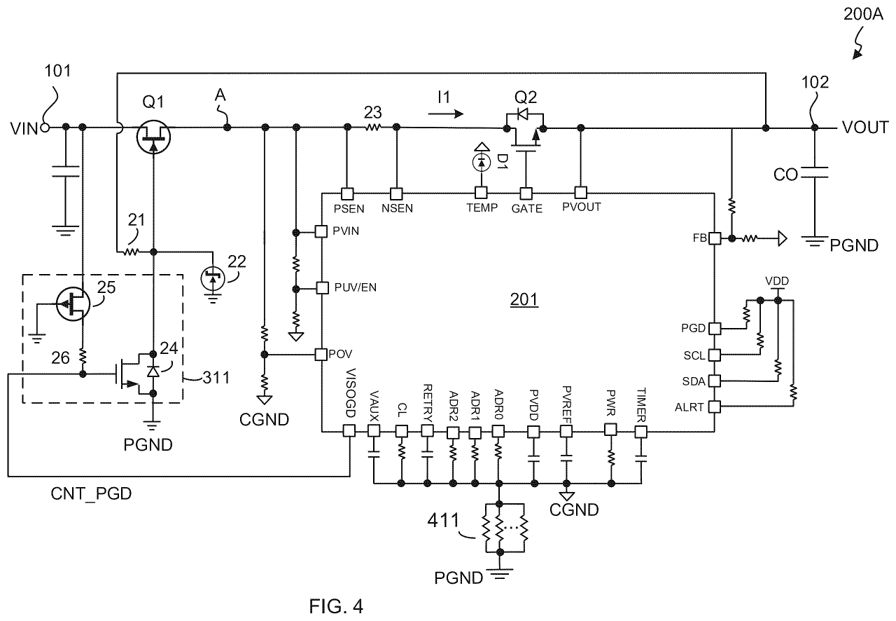

FIG. 4 shows a schematic diagram of a hot-swap circuit 200A for connecting the input power supply to the load in accordance with an embodiment of the present invention. In the example of FIG. 4, the reference circuit 411 comprises a plurality of resistors coupled in parallel to establish a virtual ground, that is the reference ground CGND. As shown in FIG. 4, by connecting the reference circuit 411 between the reference ground CGND of the integrated circuit 201 and the system ground PGND, a stable voltage reference is created that allows the integrated circuit 201 to operate within its safe operating range.

The reference circuit 411 can be implemented using passive components, such as a plurality of resistors as shown in FIG. 4. Alternatively, active components like transistors, FETs, Zener diodes, and other semiconductor devices can be used to create the virtual ground. This allows for greater flexibility in designing the reference circuit 411 to meet specific system requirements.

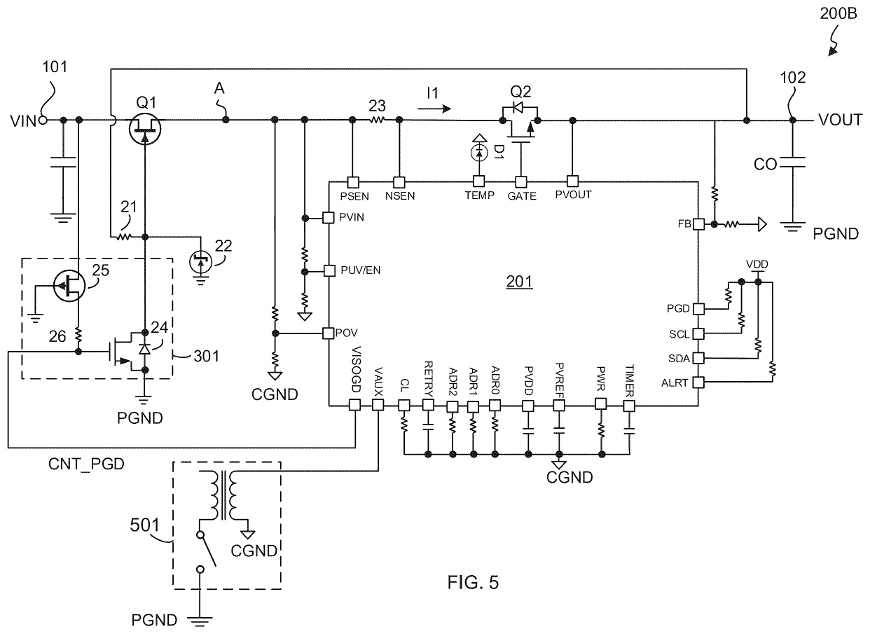

FIG. 5 shows a schematic diagram of a hot-swap circuit 200B for connecting the input power supply to the load in accordance with an embodiment of the present invention. The hot-swap circuit 200B incorporates an isolated converter 501 as the reference circuit to create virtual ground, allowing the hot-swap circuit 200B to operate over a wide range of input voltages.

The isolated converter 501 is used to provide electrical isolation between the primary side, connected to the system ground PGND, and the secondary side, connected to the reference ground CGND. By using the isolated converter 501, an isolated power supply can be created that provides a safe voltage potential for the integrated circuit 201. This allows the integrated circuit 201 to operate independently of the input node 101, reducing the risk of electrical shock or damage from high voltages. In some embodiments, the isolated converter 501 can be implemented using a variety of topologies, including flyback, forward, and push-pull converters. The choice of topology will depend on the specific requirements of the hot-swap circuit 200B.

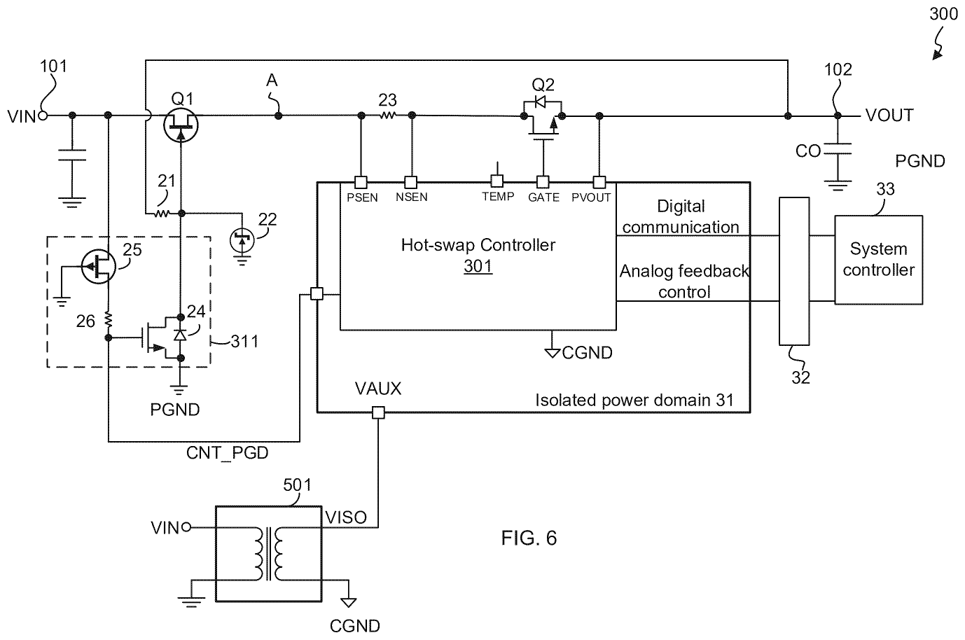

FIG. 6 shows a schematic diagram of a hot-swap circuit 300 for connecting a positive voltage input power supply to the load in accordance with an embodiment of the present invention. The hot-swap circuit 300 demonstrates how analog and digital information can be distributed to a system controller 33 from the hot-swap controller 301 using an isolation device 32, enabling reliable and flexible communication. The hot-swap controller 301 is implemented in an isolated power domain 31 created by the isolated converter 501.

The isolation device 32 may be implemented as an opto-isolator, magnetic isolator, or capacitive isolator, to maintain electrical isolation between the hot-swap controller 301 and the system controller 33. Analog feedback control and digital communication are employed between the hot-swap controller 301 and the system controller 33, allowing for precise regulation and monitoring of the hot-swap circuit. This combination of digital communication and analog feedback control enables the hot-swap circuit 300 to provide accurate and reliable control signals, while also receiving detailed fault information, telemetry data, sequencing information, and other digital data via a digital communication interface such as I2C, UART, or CAN.

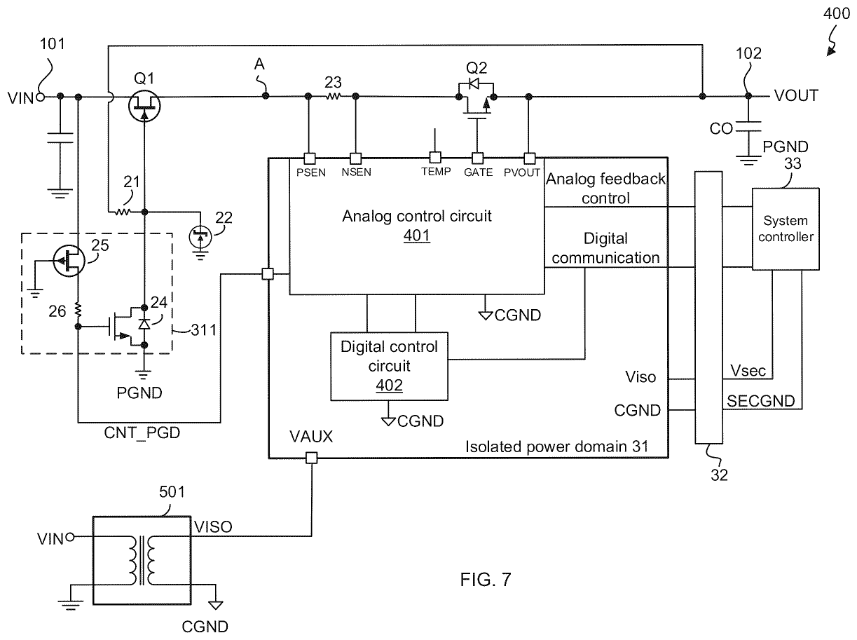

FIG. 7 shows a schematic diagram of a hot-swap circuit 400 for connecting the input power supply to the load in accordance with an embodiment of the present invention. The hot-swap circuit 400 has an analog control circuit 401 and a digital control circuit 402, which collectively form the hot-swap controller that controls the switches Q1 and Q2. The analog control circuit 401 and the digital control circuit 402 are implemented in the isolated power domain 31 created by the isolated converter 501. In one embodiment, the analog control circuit 401 and the digital control circuit 402 are integrated into a single package as one chip.

The hot-swap circuit 400 demonstrates how the analog control circuit 401 can be interfaced with the digital control circuit 402 in the isolated power domain 31 created by the isolated converter 501. Using isolated power devices, whether magnet, capacitive, or DC/DC, a voltage Vsec can be generated from a voltage VISO which is generated by the isolated converter 501 to power the system controller 33. In certain implementations of present invention, the availability of power for secondary devices can be limited. The isolated power domain for system controller 33 can be generated from the isolated power domain 31 via the isolation device 32.

In the example of FIG. 7, control signals, feedback signals, telemetry, fault information can be provided back via the isolation device 32 to the system controller 33 at a safe voltage level. The isolated power supply allows for the analog control circuit 401 and the digital control circuit 402 to control an input voltage higher than its process limit.

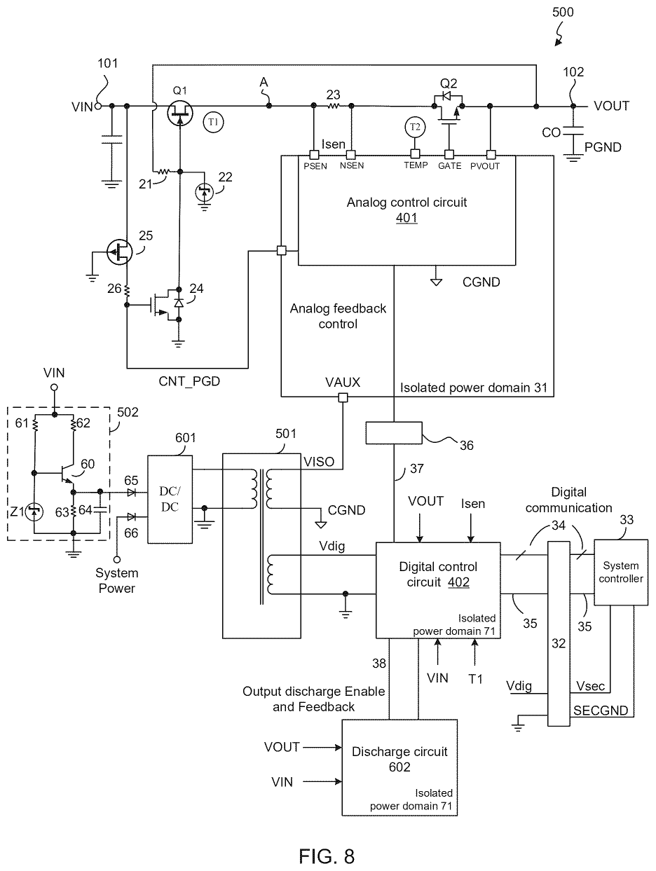

FIG. 8 shows a schematic diagram of a hot-swap circuit 500 for connecting the input power supply to the load in accordance with an embodiment of the present invention.

The hot-swap circuit 500 further includes a startup power circuit 502 to provide an initial power for the analog control circuit 401 and the digital control circuit 402. In one example, the startup power circuit 502 is created by a switch 60, a Zener diode Z1, the resistors 61-63 and a capacitor C3. The startup power circuit is not limited to implementation shown and could also be realized by other possible methods including MOSFET, JFET, transistor, resistor, capacitor, Zener diode. The startup power circuit 502 connects to a DC/DC converter 601 through a diode 65 that can be Schottky or general-purpose diode. A system power may connect to the DC/DC converter 601 through a diode 66, removing the power dissipation from the elements of the startup power circuit 502. The DC/DC converter 601 may be isolated or non-isolated converter. The output of the DC/DC converter 601 is set to a value to facilitate the application of the isolated converter 501 with low voltage and low power.

The isolated converter 501 can be a single device with multiple isolated outputs or multiple devices with single output to power each isolated domain independently. For example, the isolated converter 501 provides the voltage VISO and the reference ground CGND for powering the isolated power domain 31 which accommodates the analog control circuit 401 and provides a voltage Vdig and another reference ground for powering an isolated power domain 71 which accommodates the digital control circuit 402.

In addition, a discharge circuit 602 will provide an ability for safe discharge of the Vin and Vout for high voltage systems. The discharge implementation may include but not limited to resistor, transistor, MOSFET, JFET, Zener diode and thermal sensing device, such as NTC, PTC, thermocouple, isolated temperature sensor, digital temperature sensor, thermistor. Temperature sensors (e.g., NTC, PTC, thermocouple, isolated temperature sensor, digital temperature sensor, thermistor) T1 and T2 in this embodiment provide thermal monitoring and management for the JFET Q1 and the switch Q2. These sensors may also include direct sensing on the die of the JFET Q1 and the switch Q2.

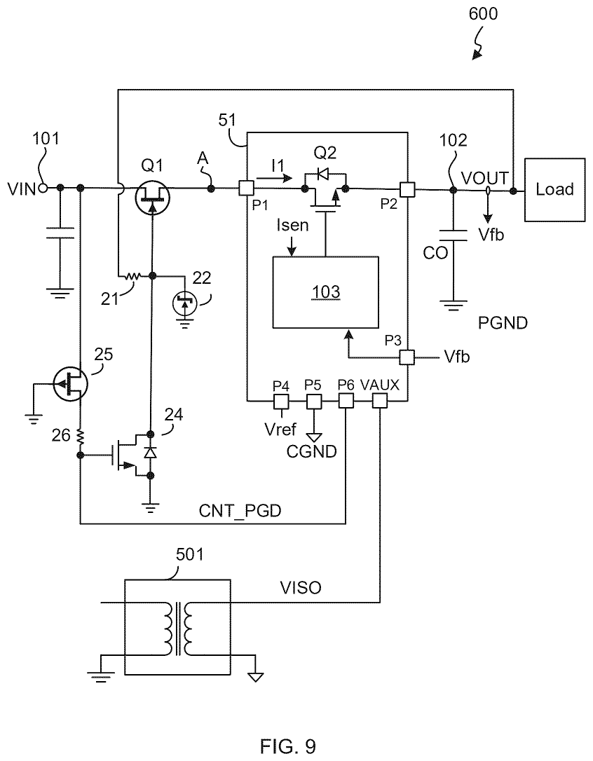

FIG. 9 shows a schematic diagram of a hot-swap circuit 600 for connecting the input power supply to the load in accordance with an embodiment of the present invention. The switch Q2 and hot-swap controller 103 are integrated into a single integrated circuit 51, which can be implemented as a co-packed or monolithic design.

The integrated circuit 51 has a plurality of pins, including but not limited to P1-P6. Specifically, the switch Q2 is connected between pins P1 and P2, with the pin P1 connected to the source of the JFET Q1 and the pin P2 connected to the output node 102. Additionally, the pin P3 is designated to receive the feedback voltage Vfb, while the pin P4 is configured to receive a power supply voltage Vref, which powers the hot-swap controller 103. The pin P5 is coupled to the reference ground CGND, ensuring proper grounding of the integrated circuit 51.

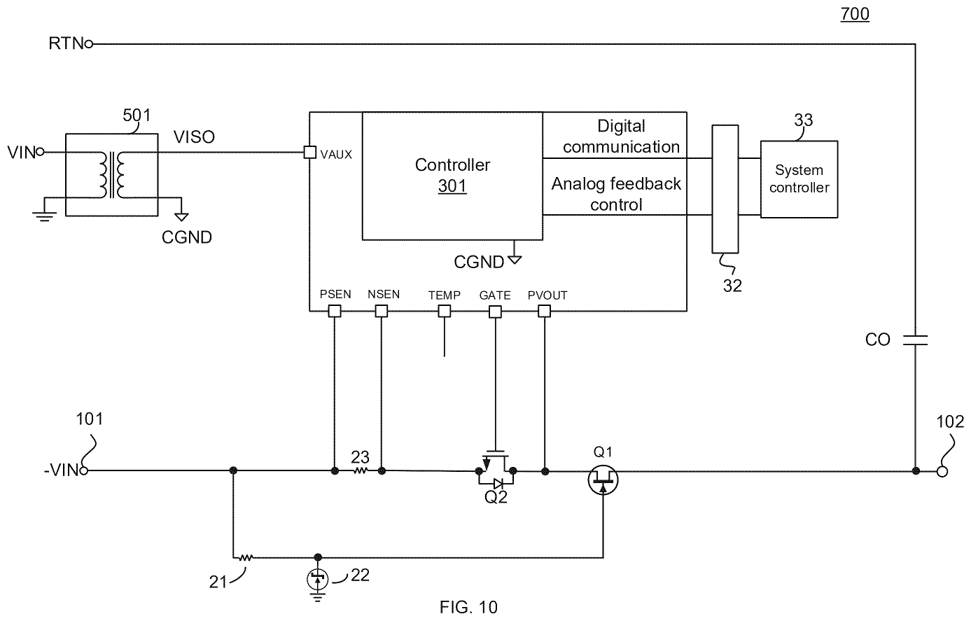

FIG. 10 shows a schematic diagram of a hot-swap circuit 700 for connecting a negative voltage input power supply to the load in accordance with alternate embodiment of the present invention. The negative voltage input power supply provides a negative input voltage −Vin. Notably, the hot-swap circuit 700 is particularly suited for applications where the negative input voltage Vin is extremely negative, such as −800 volts, requiring specialized control and protection mechanisms to ensure safe and efficient operation.

The hot-swap circuit 700 demonstrates the distribution of analog and digital information to a larger system, such as the system controller 33, utilizing isolation techniques through the isolation device 32. The isolation methods employed may include opto-isolators, magnetic isolators, or capacitive isolators, among others. This embodiment enables comprehensive control and feedback to the system at large, including the system controller 33, as well as the transmission of detailed fault information, telemetry data, sequencing details, and other digital data via a digital communication interface. The digital communication interface may support various protocols, such as I2C, UART, or CAN, allowing for flexible and reliable communication. Furthermore, one skilled in the art can extend the inventive concept presented in FIG. 7 to enhance this embodiment (e.g., based on what shown in FIGS. 6-8), demonstrating the versatility and adaptability of the present invention.

While specific embodiments of the present invention have been provided, it is to be understood that these embodiments are for illustration purposes and not limiting. Embodiments of the present invention only demonstrate positive voltage applications. This invention can provide the same operation in negative voltage applications. Many additional embodiments will be apparent to persons of ordinary skill in the art reading this disclosure.

We claim:

1. A hot-swap circuit, comprising:
an input node, an output node, an input return node and an output return node, wherein the hot-swap circuit is configured to receive an input voltage between the input node and the input return node, the hot-swap circuit is configured to provide the output voltage between the output node and the output return node, wherein the input return node and the output return node are connected to a power ground;
a normally-on JFET and a first switch connected in series between the input node and the output node, wherein the hot-swap circuit connects the output node to the input node when both the normally-on JFET and the first switch are turned on;
a drive circuit configured to connect a gate of the normally-on JFET to the output node; and
a hot-swap controller configured to control the first switch based on the output voltage and a current flowing through the first switch.

2. The hot-swap circuit of claim 1, wherein a voltage across a drain and a source of the first switch is clamped to being no higher than a voltage level.

3. The hot-swap circuit of claim 2, wherein the voltage level is a pinch-off voltage of the normally-on JFET.

4. The hot-swap circuit of claim 1, wherein the hot-swap controller is configured to increase the output voltage from a first voltage to a second voltage during a soft start period, with the current flowing through the first switch limited to less than a first current level during the soft start period, and the current flowing through the first switch limited to less than a second current level after the soft start period.

5. The hot-swap circuit of claim 4, wherein the first current level is less than the second current level.

6. The hot-swap circuit of claim 1, wherein the input voltage is higher than 180V or lower than −180V.

7. The hot-swap circuit of claim 1, further comprising:
a turn-on circuit configured to control a turn-on sequence of the normally-on JFET; wherein
the turn-on circuit comprises a second switch and a third switch, the second switch is coupled between the gate of the normally-on JFET and the power ground, the third switch is coupled between the input node and a gate of the second switch, the gate of the second switch is coupled to the hot-swap controller to receive a reference signal, and the gate of the third switch is coupled to the power ground.

8. The hot-swap circuit of claim 1, further comprising a reference circuit to create a virtual ground for the hot-swap controller, such that the hot-swap controller is in an isolated power domain isolated from the power ground.

9. The hot-swap circuit of claim 8, wherein the reference circuit is selected from a group consisting of an isolated converter, and a plurality of resistors.

10. The hot-swap circuit of claim 1, wherein analog feedback control and digital communication are employed between the hot-swap controller and a system controller, to provide precise regulation and monitoring of the hot-swap circuit.

11. The hot-swap circuit of claim 1, wherein the hot-swap controller is configured to implement a plurality of functions, which are selected from a group consisting of fault control, telemetry control, status control, temperature control, soft start control, current protection, and sequencing control.

12. The hot-swap circuit of claim 1, further comprising:
a startup power circuit configured to provide an initial voltage; and
an isolated converter connected to the startup power circuit to receive the initial voltage, wherein the isolated converter is configured to provide more than one isolated output voltage, each powering a separate isolated power domain.

13. The hot-swap circuit of claim 11, wherein:
the hot-swap controller comprises an analog control circuit and a digital control circuit, the isolated converter is configured to provide a first voltage and a second voltage; and
wherein the first voltage powers the analog control circuit in a first isolated power domain, and the second voltage powers the digital control circuit in a second isolated power domain.

14. A method of operating a hot-swap circuit, comprising:
receiving an input voltage between an input node and an input return node;
providing an output voltage between an output node and an output return node;
controlling a switch connected in series with a normally-on JFET between the input node and the output node based on the output voltage and a current flowing through the switch; and
connecting the output node to the input node when both the normally-on JFET and the switch are turned on, wherein a gate of the normally-on JFET is connected to the output node.

15. The method of claim 14, further comprising:
clamping a voltage across a drain and a source of the first switch to being no higher than a voltage level.

16. The method of claim 14, further comprising:
increasing the output voltage from a first to a second voltage during a soft start period;
limiting the current flowing through the switch to less than a first current level during the soft start period; and
limiting the current flowing through the switch to less than a second current level after the soft start period.

17. The method of claim 14, further comprising:
controlling a turn-on sequence of the normally-on JFET through a turn-on circuit; and
providing a reference signal to control the turn-on circuit.

18. The method of claim 14, further comprising:
creating a virtual ground for a hot-swap controller which controls the switch; wherein
the hot-swap controller is in an isolated power domain isolated from a power ground to which the input return node and the output return node are connected.

19. The method of claim 14, further comprising:
providing analog feedback control and digital communication to a system controller by a hot-swap controller which controls the switch.

20. The method of claim 14, further comprising:
providing an initial voltage;
converting the initial voltage to a first voltage and a second voltage via an isolated converter;
powering an analog control circuit in a first isolated power domain with the first voltage; and
powering a digital control circuit in a second isolated power domain with the second voltage.
